(19) United States
(12) Patent Application Publication
(10) Pub. No.: US 2026/0075302 A1
(43) Pub. Date: Mar. 12, 2026

(54) MAPPING DEVICE AND MAPPING METHOD

(71) Applicant: Sinfonia Technology Co., Ltd., Tokyo (JP)

(72) Inventors: Keigo Sato, Tokyo (JP); Yuji Miyashita, Tokyo (JP)

(73) Assignee: Sinfonia Technology Co., Ltd., Tokyo (JP)

(21) Appl. No.: 19/325,832

(22) Filed: Sep. 11, 2025

(30) Foreign Application Priority Data
Sep. 12, 2024 (JP) 2024-158323

(51) Int. Cl. H04N 23/56; G06T 7/00; H01L 21/67

(52) U.S. Cl. CPC H04N 23/56; G06T 7/0004; H10P 72/0608; G06T 2207/30148

(57) ABSTRACT

A load port detects an accommodation state of a plurality of substrates, which are accommodated in a FOUP while being arranged in a thickness direction. The load port includes an emitter, a camera, and a controller. The controller performs, by using information on an amount of change in a plurality of pixel values according to coordinates in the thickness direction, double determination as to whether two or more substrate are accommodated in an accommodation region in an imaging region, the accommodation region being a region for accommodating one of the plurality of substrates.

### CROSS-REFERENCE TO RELATED APPLICATION

This application is based upon and claims the benefit of priority from Japanese Patent Application No. 2024-158323, filed on Sep. 12, 2024, the entire contents of which are incorporated herein by reference.

### TECHNICAL FIELD

The present disclosure relates to a mapping device and a mapping method.

### BACKGROUND

Patent Document 1 discloses a mapping device that determines an accommodation state of substrates in a FOUP (container). The mapping device determines the accommodation state of the substrates by using imaging data (image information) obtained by a camera in a state in which end surfaces of the substrates are illuminated by lighting. More specifically, when a thickness of a substrate detected based on the imaging data is greater than a thickness of one sheet of substrate, it is determined that the substrate is stored in a state in which two or more substrates overlap with another (a double state has occurred).

### PRIOR ART DOCUMENT

### Patent Document

Patent Document 1: Japanese Patent Laid-open Publication No. 2024-60329 Although not disclosed in Patent Document 1, the following procedure may be considered as an example of a specific procedure for detecting a thickness of a substrate. First, in image information, a pixel value (value indicating brightness) at each coordinate in a thickness direction of substrates is compared with a predetermined threshold value to determine that a substrate exists at a coordinate where the pixel value is equal to or greater than the threshold value. Further, a length in the thickness direction (i.e., thickness) of a portion where the pixel value is equal to or greater than the threshold value is compared with a reference thickness value to determine whether or not two or more substrates exist. Thus, a determination is made as to whether or not a double state has occurred. However, in the above-mentioned means of comparing the pixel value itself with the threshold value, influence of light reflected from an inner wall surface of a container may be significant according to a type of the container, and therefore further improvement in detection accuracy may be required.

### SUMMARY

The present disclosure provides a technique capable of reliably detecting an accommodation state of substrates.

A mapping device according to a first configuration is a mapping device for detecting an accommodation state of a plurality of substrates, which are accommodated in a container while being arranged in a predetermined thickness direction, and includes: a light emitter configured to emit light toward at least an interior of the container; an imager configured to image a predetermined imaging region by sensing reflection light of the light emitted from the light emitter to obtain image information; and a determiner configured to determine the accommodation state of the substrates by using the image information, wherein the image information includes information on a plurality of pixel values that indicate intensities of the reflection light at corresponding coordinates in the thickness direction, and wherein the determiner determines, by using information on an amount of change in the plurality of pixel values according to the coordinates in the thickness direction, whether two or more substrates are accommodated in an accommodation region in the imaging region, the accommodation region being a region for accommodating one of the plurality of substrates.

With this configuration, the determination is made by using the information on the amount of change in the pixel values in the thickness direction. Since the substrate is generally very thin compared to an inner wall of the container, the pixel value corresponding to light reflected from an end surface of the substrate changes rapidly according to the coordinate in the thickness direction. Conversely, since the inner wall surface of the container has a certain length in the thickness direction, light reflected from the inner wall surface of the container may be detected over a wide region in the thickness direction. Therefore, it is presumed that the amount of change in the pixel values corresponding to the light reflected from the inner wall surface in the thickness direction is gentler than an amount of change in pixel values relating to the end surface of the substrate. Accordingly, by using the information on the change in the pixel values in the thickness direction, influence of the light reflected from the inner wall surface of the container can be suppressed during the determination. Thus, it is possible to more reliably detect the accommodation state of substrates.

In a second configuration of the mapping device, the determiner may obtain numerical information indicating one of the number of peaks of the pixel values, the number of times the pixel values start increasing, and the number of times the pixel values stop decreasing, based on the information on the amount of change, and in the determination, may count the number of the substrates in the accommodation region based on the numerical information.

According to a processing state of the end surface of the substrate, a thickness of a portion of the end surface that reflects light toward the imager may be quite small. For this reason, a detected value of the thickness of the substrate may be much smaller than an actual thickness. Even in such a situation, with this configuration, the determination can be made by counting the number of substrates in the accommodation region. Accordingly, it is possible to more reliably detect the accommodation state of substrates.

In a third configuration of the mapping device, the determiner may use, in the determination, information on the pixel values in addition to the information on the amount of change.

With this configuration, the information on the pixel values can be used as an auxiliary in the determination. Accordingly, accuracy of detecting the accommodation state of substrates can be further improved compared to a case where only the information on the amount of change in the pixel values is used.

A mapping method according to a fourth configuration is a mapping method performed in a mapping device for detecting an accommodation state of a plurality of substrates, which are accommodated in a container while being arranged in a predetermined thickness direction, and includes: emitting light toward at least an interior of the container; imaging a predetermined imaging region by sensing reflection light of the light to obtain image information; and determining the accommodation state of the substrates by using the image information, wherein the image information includes information on a plurality of pixel values that indicate intensities of the reflection light at corresponding coordinates in the thickness direction, and wherein the determining includes determining, by using information on an amount of change in the plurality of pixel values according to the coordinates in the thickness direction, whether two or more substrates are accommodated in an accommodation region in the imaging region, the accommodation region being a region for accommodating one of the plurality of substrates.

With this configuration, like the first configuration, it is possible to more reliably detect the accommodation state of substrates.

### BRIEF DESCRIPTION OF DRAWINGS

The accompanying drawings, which are incorporated in and constitute a part of the specification, illustrate embodiments of the present disclosure.

FIG. 1 is a schematic plan view of an EFEM, which has a load port according to the present embodiment, and surroundings of the EFEM.

FIG. 2 is a right side view of the load port.

FIG. 3 is a diagram schematically showing a positional relationship between a substrate and a camera.

FIG. 4 is a diagram showing an imaging region imaged by the camera.

FIGS. 5A and 5B are diagrams showing an operation of the load port.

FIGS. 6A and 6B are diagrams showing an operation of the load port.

FIG. 7 is a flowchart showing an entire mapping process.

FIG. 8 is a flowchart showing a determination process for each substrate.

FIGS. 9A to 9D are diagrams for explaining the determination of the accommodation state of substrates.

FIG. 10 is a diagram schematically showing an example of a set of pixel values.

FIG. 11 is a diagram showing a first-order differential filter.

FIG. 12 is a diagram showing a set of difference values obtained by applying the first-order differential filter to the pixel values.

FIG. 13 is a diagram showing a set of absolute values of the difference values.

FIG. 14 is a graph showing a relationship between pixel values and Y coordinates.

FIG. 15 is a graph showing a relationship between difference values and Y coordinates.

FIG. 16 is a graph showing a relationship between gradient intensities and Y coordinates.

FIG. 17 is a flowchart showing a procedure for double determination.

FIG. 18 is a flowchart showing a procedure for double determination according to a modification.

FIG. 19 is a flowchart showing a procedure for double determination according to another modification.

FIG. 20 is a diagram showing a noise removal filter according to still another modification.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

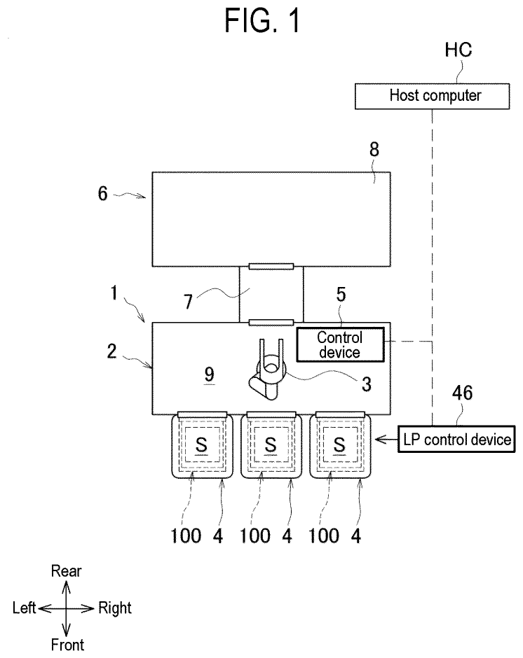

An embodiment of the present disclosure (hereinafter referred to as the present embodiment) will be described. For ease of description, directions shown in FIG. 1 are defined as front-rear and left-right directions. More specifically, a direction in which an EFEM 1 (described later) and a processing apparatus 6 (described later) are arranged side by side is defined as the front-rear direction. In the front-rear direction, a side on which the EFEM 1 is disposed is defined as a front side. In the front-rear direction, a side on which the processing apparatus 6 is disposed is defined as a rear side. A direction in which a plurality of load ports 4 are arranged side by side, which is orthogonal to the front-rear direction, is defined as the left-right direction. A direction orthogonal to both the front-rear direction and the left-right direction is defined as an up-down direction. The up-down direction is a direction parallel to a vertical direction in which gravity acts.

### Overall Configuration of Load Port and its Surroundings

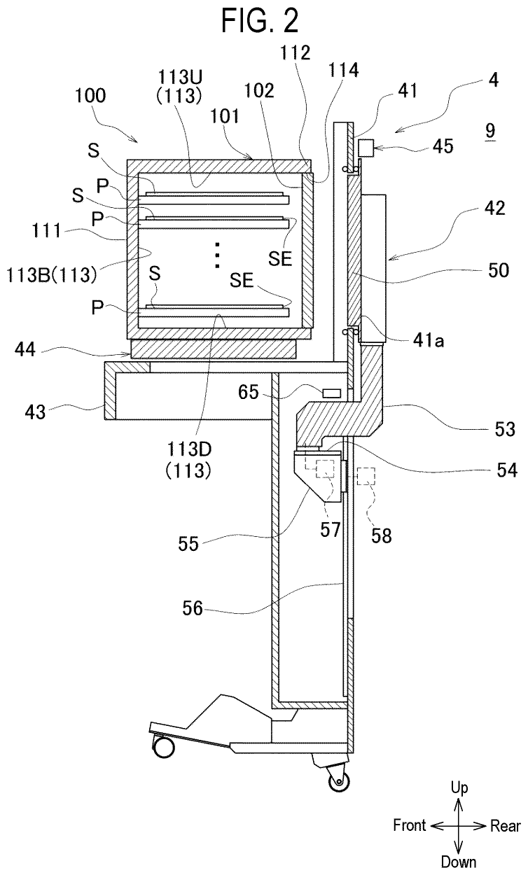

The load port 4 (a mapping device of the present disclosure) according to the present embodiment and its surroundings will be described with reference to FIG. 1. FIG. 1 is a schematic diagram of the EFEM 1 having the load ports 4 and surroundings of the EFEM 1. “EFEM” is an abbreviation for “Equipment Front End Module.” The EFEM 1 is a device for transferring a substrate S between a below-described FOUP 100 (a container of the present disclosure) placed on each load port 4 and the processing apparatus 6. For example, a semiconductor circuit (not shown) is formed on the substrate S. Examples of types of the substrate S include well-known semiconductor substrates (including wafers), glass substrates, and glass epoxy substrates. The substrate S is, for example, substantially rectangular when viewed from the up-down direction. The substrate S has an end surface SE (see FIG. 2) extending, for example, along the up-down direction.

As shown in FIG. 1, the EFEM 1 includes a housing 2, a transfer robot 3, the plurality of load ports 4, and a control device 5. The processing apparatus 6 is disposed on the rear side of the EFEM 1.

The EFEM 1 is installed at a predetermined site in, for example, a semiconductor factory. The EFEM 1 transfers the substrate S between the FOUP 100 placed on the load port 4 and the processing apparatus 6 by using the transfer robot 3 disposed in a transfer space 9 in the housing 2. “FOUP” is an abbreviation for “Front-Opening Unified Pod.” The FOUP 100 is a container capable of accommodating a plurality of substrates S arranged in the up-down direction. The FOUP 100 is transferred by, for example, a FOUP transfer device (not shown). The FOUP 100 is transferred between the FOUP transfer device and the load port 4. A thickness direction of each substrate S is substantially parallel to the up-down direction.

The housing 2 forms the transfer space 9 in which the substrate S is transferred. The transfer space 9 is separated from a space outside the housing 2 (external space). The plurality of load ports 4 are connected to a front end of the housing 2. A load lock chamber 7 of the processing apparatus 6 is connected to the rear end of the housing 2. The transfer robot 3 transfers the substrate S between the FOUP 100 and the load lock chamber 7.

The plurality of load ports 4 are arranged, for example, side by side in the left-right direction. The plurality of load ports 4 are attached to the front end of the housing 2. Each load port 4 is configured to receive the FOUP 100. Each load port 4 is configured to attach and detach a lid 102 (see FIG. 2) to a FOUP body 101 (see FIG. 2) of the FOUP 100. Each load port 4 is configured to be capable of performing mapping of a plurality of substrates S accommodated in the FOUP body 101.

The control device 5 is electrically connected to a controller (not shown) of the transfer robot 3, a load port (LP) control device 46 (described later) of the load port 4, and a controller (not shown) of the processing apparatus 6. The control device 5 is configured to communicate with these controllers. The control device 5 may be electrically connected to a host computer HC.

The processing apparatus 6 is an apparatus that performs a predetermined process, such as a film formation process, an etching process, packaging, bonding, molding, or the like, on the substrate S. The processing apparatus 6 includes, for example, the load lock chamber 7 for causing the substrate S to temporarily wait, and a processing chamber 8 for performing the predetermined process on the substrate S.

### Load Port

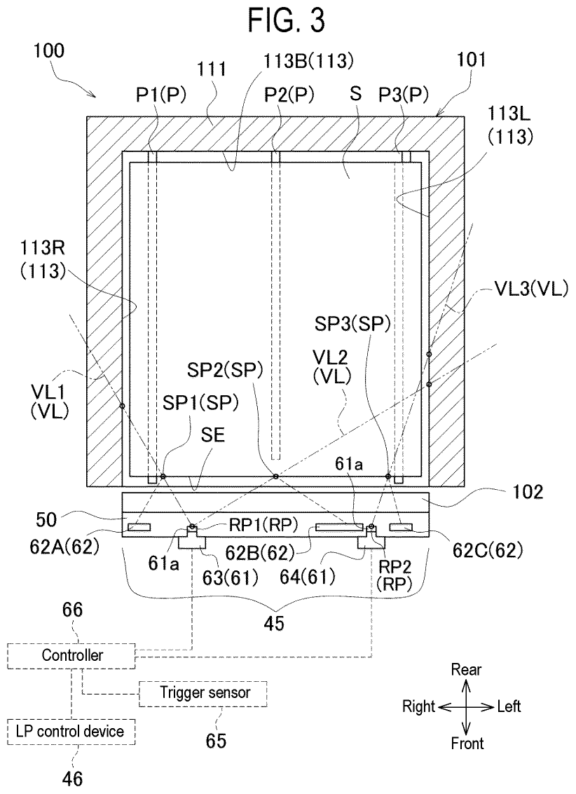

A configuration of the load port 4 will be described with reference to FIGS. 2 and 3. FIG. 2 is a right side view of the load port 4. FIG. 3 is a diagram schematically showing a positional relationship between the substrate S and a plurality of cameras 61 described later (the positional relationship will be described later).

The load port 4 removes the lid 102 of the FOUP 100 from the FOUP body 101, and performs mapping of the plurality of substrates S accommodated in the FOUP body 101. As shown in FIG. 2, the load port 4 includes, for example, a base 41, a door mechanism 42, a support frame 43, a stage 44, a scanner 45, and an LP control device 46 (see FIG. 1).

The base 41 is a substantially flat plate-shaped member. The base 41 has a substantially rectangular shape when viewed from the front-rear direction. The base 41 is disposed to extend in the up-down direction. The base 41 is fixed to the EFEM 1. The base 41 is a portion of a partition wall that separates the transfer space 9 from the external space. The base 41 has a substantially rectangular opening 41a. The opening 41a is disposed in an upper portion of the base 41. The opening 41a has a size that allows the lid 102 of the FOUP 100 to pass therethrough in the front-rear direction. The opening 41a is opened and closed by a door body 50 described below.

The door mechanism 42 attaches and detaches the lid 102 to and from the FOUP body 101. As shown in FIG. 2, the door mechanism 42 includes, for example, the door body 50, a door support 53, a guide rail 54, a lifting block 55, a guide rail 56, a motor 57, and a motor 58.

The door body 50 is a plate-like member. When viewed from the front-rear direction, the door body 50 has a substantially rectangular shape. The door body 50 is supported by, for example, the door support 53. The door body 50 is provided with, for example, an attracting holder (not shown) and a latch key (not shown). The attracting holder attracts and holds the lid 102 on a front surface of the door body 50. The lid 102 is fixed to the FOUP body 101 by a locking mechanism (not shown). The latch key operates the locking mechanism to lock and unlock the lid 102 of the FOUP 100.

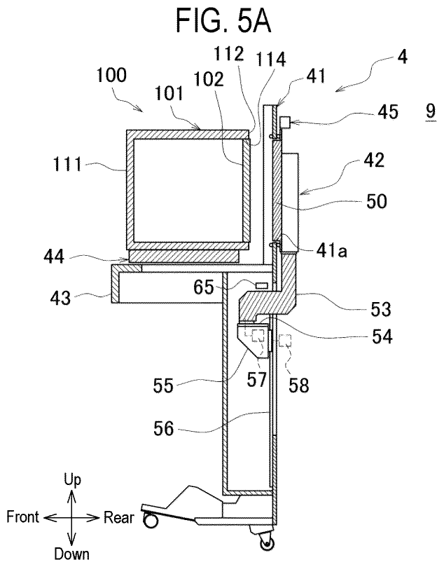

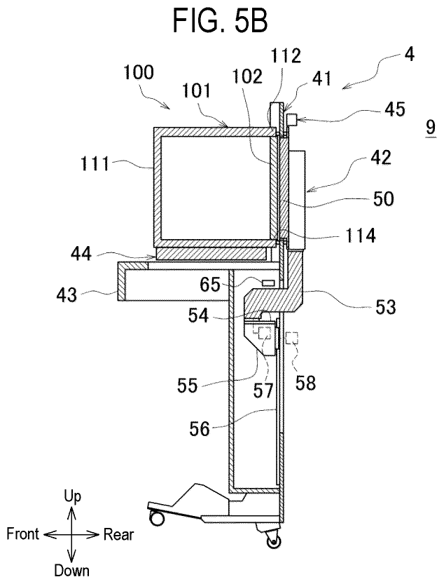

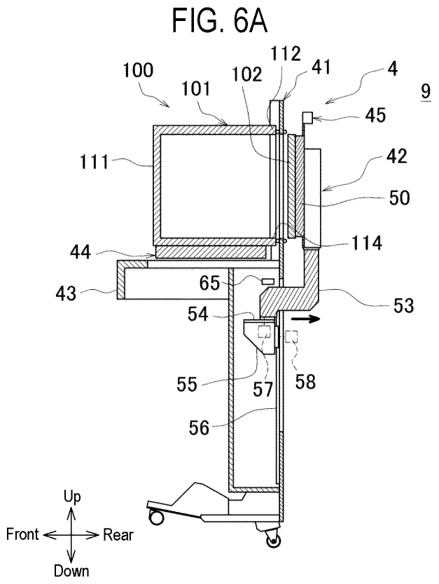

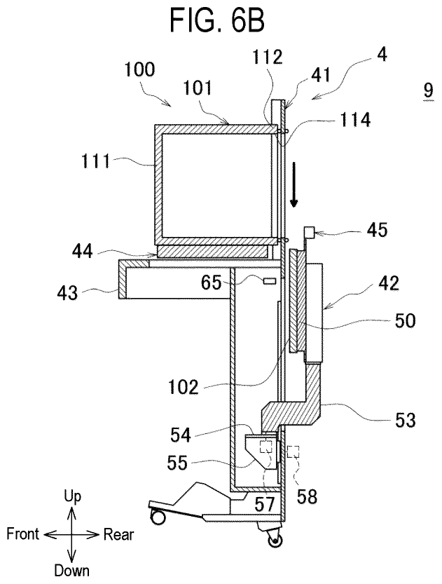

The door support 53 is a member that supports the door body 50. The door support 53 is supported by the guide rail 54 so as to be movable in the front-rear direction. The door support 53 is driven by the motor 57 to move in the front-rear direction. The door support 53 is moved in the front-rear direction to move the door body 50 between a closed position (see FIG. 5B) and an open position (see FIG. 6A). The closed position is a position of the door body 50 at which the door body 50 closes the opening 41a of the base 41. The open position is a position on a rear side of the closed position, and is a position of the door body 50 at which the door body 50 opens the opening 41a. The guide rail 54 is a member that guides the door support 53 in the front-rear direction. The guide rail 54 is provided on the lifting block 55. The lifting block 55 is a member for moving the door body 50 in the up-down direction. The lifting block 55 supports the door support 53 so as to be movable in the front-rear direction. The lifting block 55 is guided in the up-down direction along the guide rail 56. The lifting block 55 is driven by the motor 58 to move in the up-down direction. The lifting block 55 is moved in the up-down direction to move the door body 50 between the above-mentioned open position (see FIG. 6A) and a retracted position (see FIG. 6B) below the open position. The guide rail 56 is a member that guides the lifting block 55 in the up-down direction. The guide rail 56 is attached to the base 41, for example. The guide rail 56 extends in the up-down direction.

The motor 57 drives the door support 53 to move in the front-rear direction. The motor 57 is, for example, a well-known stepping motor. The motor 57 is controlled by the LP control device 46. The motor 58 drives the lifting block 55 to move in the up-down direction. The motor 58 is, for example, a well-known stepping motor. The motor 58 is configured to be capable of controlling a position of the door support 53 in the up-down direction by being controlled by the LP control device 46.

The support frame 43 is a member that supports the stage 44. The support frame 43 is fixed to the base 41. The support frame 43 extends forward from a portion in the base 41 in the up-down direction. The stage 44 is a platform-like member on which the FOUP 100 is placed.

The stage 44 is supported by the support frame 43. The stage 44 is configured to be movable in the front-rear direction relative to the support frame 43. The stage 44 is moved by a drive mechanism (not shown) between a predetermined delivery position (see FIG. 5A) and a lid opening/closing position (see FIG. 5B) on a rear side of the delivery position. The delivery position is a position of the stage 44 at which the FOUP 100 is delivered to and from the FOUP transfer device (not shown).

The scanner 45 is a member for detecting the plurality of substrates S in the FOUP 100. The scanner 45 is disposed in, for example, the transfer space 9. The scanner 45 may be fixed to, for example, the door body 50. Thus, the scanner 45 is driven by the motor 58 to move together with the door body 50 in the up-down direction. As shown in FIG. 3, the scanner 45 includes the plurality of cameras 61, a light emitter 62, a trigger sensor 65, and a controller 66 (a determiner of the present disclosure). The controller 66 may be provided in a housing (not shown) of each camera 61.

Each of the plurality of cameras 61 is a device for obtaining imaging data (image information of the present disclosure) of a plurality of substrates S. Each camera 61 is configured and disposed to be capable of imaging the plurality of substrates S at once, for example. The plurality of substrates S referred to herein means, for example, some of the substrates S among all the substrates S accommodated in the FOUP 100. Alternatively, each camera 61 may be capable of imaging the plurality of substrates S one by one. In addition, in the present embodiment, “imaging” means that an image of an object is recorded (i.e., photographed) by each camera 61. Each camera 61 is configured and disposed to image a part of the substrate S in the left-right direction. Each camera 61 is configured to image at least a part of the end surface SE of the substrate S (more specifically, a rear end surface of the substrate S). The plurality of cameras 61 may be disposed, for example, on an upper side of the door body 50, and arranged in the left-right direction. Each camera 61 is electrically connected to the controller 66. Each camera 61 includes, for example, a light receiving lens 61a and an imaging element not shown. The light receiving lens 61a is a light collecting member configured to receive light and focus the light on the imaging element. A surface of the light receiving lens 61a faces, for example, the front side (FOUP side). The imaging element is, for example, a well-known device such as a CCD or the like. The imaging element detects light, converts the light into an electrical signal, and transmits the electrical signal to the controller 66.

As shown in FIG. 3, the plurality of cameras 61 include, for example, a first camera 63 and a second camera 64 (imager of the present disclosure) different from the first camera 63. The first camera 63 is, for example, a low magnification camera with a large horizontal angle of view. For the sake of simplicity of explanation, it is assumed that the first camera 63 in the present embodiment is a monochrome camera, but the present disclosure is not limited thereto. The first camera 63 may be a color camera. The horizontal angle of view of the first camera 63 is a horizontal angle of view in which a vicinity of a first pole P1 and a vicinity of a second pole P2 are included in the field of view. As a specific example, when mapping a substrate S of, for example,510 mm×515 mm, the horizontal angle of view may be 100 degrees or more. More specifically, the horizontal angle of view may be 100 degrees or more and 150 degrees or less. A resolution of the first camera 63 is, for example, 2.3 million pixels. An imaging axis of the first camera 63 is, for example, substantially parallel to the front-rear direction (in other words, substantially horizontal). The horizontal angle of view, the resolution, and the orientation of the imaging axis of the first camera 63 are not limited those described above.

The second camera 64 is, for example, a high magnification camera with a smaller horizontal angle of view than the first camera 63. For the sake of simplicity of explanation, it is assumed that the second camera 64 in the present embodiment is a monochrome camera, but the present disclosure is not limited thereto. The second camera 64 may be a color camera. The horizontal angle of view of the second camera 64 may be, for example, 30 degrees or more and 35 degrees or less. The horizontal angle of view may be particularly 34 degrees or more. A resolution of the second camera 64 is, for example, 2.3 million pixels. An imaging axis of the second camera 64 is, for example, substantially parallel to the front-rear direction (in other words, substantially horizontal). The horizontal angle of view, the resolution, and the orientation of the imaging axis of the second camera 64 are not limited to those described above.

The light emitter 62 is, for example, a lighting device for illuminating an inside of the FOUP 100. The light emitter 62 includes, for example, a plurality of light sources 62A, 62B, and 62C (hereinafter also referred to as light sources 62A to 62C). The light source 62A and the light source 62B are light sources provided correspondingly to the first camera 63. The light source 62C is a light source provided correspondingly to the second camera 64. Each of the light sources 62A to 62C includes, for example, LED elements (not shown). Light (irradiation light) is irradiated from the light emitter 62 toward at least the inside of the FOUP 100.

A part of the irradiation light emitted from the light emitter 62 and traveling forward is reflected backward by the substrate S or an inner wall surface 113 described below. Hereinafter, such light is referred to as reflection light. In particular, the reflection light reflected by the end surface SE (more specifically, the rear end surface) of the substrate S is used to detect the substrate S. A part of the irradiation light (see the dashed line in FIG. 3) is reflected by the end surface SE and then sensed by one of the plurality of cameras 61. The imaging element of each camera 61 senses the reflection light to image a portion of the rear end surface of the substrate S in the left-right direction and a background of the portion, thereby obtaining imaging data. The imaging data obtained by the imaging element is transferred to the controller 66.

The trigger sensor 65 is a sensor for use in determining a timing for starting imaging by the plurality of cameras 61. The trigger sensor 65 may be configured to be capable of detecting movement of the door support 53 when a portion of the door support 53 moves in the up-down direction, for example. The trigger sensor 65 sends a signal indicating the movement of the door support 53 to the controller 66.

The controller 66 is for executing a mapping process described below. The controller 66 includes a CPU, a ROM, and a RAM (memory), which are not shown. The controller 66 performs calculations for the mapping process by the CPU according to a program stored in the ROM. The controller 66 is electrically connected to the LP control device 46, the plurality of cameras 61, and the trigger sensor 65. The controller 66 may have a well-known internal storage, such as a well-known NAND flash memory, an HDD, or an SSD, which are not shown.

The LP control device 46 includes a CPU, a ROM, and a RAM (memory), none of which are shown. The LP control device 46 controls individual mechanisms of the load port 4 by the CPU according to a program stored in the ROM. The LP control device 46 also communicates with the control device 5 of the EFEM 1, the host computer HC, and the like. The LP control device 46 also sends information relating to the mapping process to the controller 66 (described later). (FOUP) Next, a more specific example of the configuration of the FOUP 100 will be described with reference to FIGS. 2 and 3. The front-rear and left-right directions shown in FIG. 3 are directions for convenience of explanation when an opening 114, which will be described later, faces the rear side. It should be noted that the left-right direction shown in FIG. 3 is opposite to the left-right direction on the paper plane in FIG. 3.

The FOUP 100 is a container having a substantially rectangular parallelepiped shape. The FOUP 100 can accommodate a plurality of substrates S arranged in the up-down direction. As shown in FIGS. 2 and 3, the FOUP 100 includes the FOUP body 101 and the lid 102. The FOUP body 101 is a member having a substantially rectangular parallelepiped shape. The FOUP body 101 can be supported by the stage 44. The FOUP body 101 has, for example, a wall 111, an open portion 112, and a plurality of poles P.

The wall 111 is a substantially rectangular parallelepiped member disposed to surround an internal space of the FOUP 100. The wall 111 is formed, for example, by fixing a plurality of substantially flat plate-shaped members to one another with fixing tools (not shown). The wall 111 has a plurality of inner wall surfaces 113 (see FIGS. 2 and 3). The open portion 112 is disposed, for example, at a rear end of the FOUP body 101. The open portion 112 has the opening 114 that is substantially rectangular when viewed from the front-rear direction.

Each of the plurality of inner wall surfaces 113 is disposed to face the inside of the FOUP 100. Each inner wall surface 113 is, for example, substantially rectangular. The plurality of inner wall surfaces 113 include a rear surface 113B, an upper surface 113U (see FIG. 2), a lower surface 113D (see FIG. 2), a left side surface 113L (see FIG. 3), and a right side surface 113R (see FIG. 3). The rear surface 113B is the inner wall surface 113 disposed at the frontmost side among the plurality of inner wall surfaces 113. In FIG. 3, the rear surface 113B faces the rear side (i.e., a side of the opening 114 in the front-rear direction). The rear surface 113B extends in the up-down direction and the left-right direction. The rear surface 113B is disposed on an opposite side to the opening 114 across a center of the FOUP body 101 in the front-rear direction. The upper surface 113U is connected to an upper end of the rear surface 113B and extends to the rear end of the FOUP body 101 in the front-rear direction. The upper surface 113U faces downward. The lower surface 113D is connected to a lower end of the rear surface 113B and extends to the rear end of the FOUP body 101 in the front-rear direction. The lower surface 113D faces upward. The left side surface 113L is connected to each of a left end of the rear surface 113B, a left end of the upper surface 113U, and a left end of the lower surface 113D, and extends to the rear end of the FOUP body 101 in the front-rear direction. The left side surface 113L faces rightward. The right side surface 113R is connected to each of a right end of the rear surface 113B, a right end of the upper surface 113U, and a right end of the lower surface 113D, and extends to the rear end of the FOUP body 101 in the front-rear direction. The right side surface 113R faces leftward.

The plurality of poles P support the plurality of substrates S substantially horizontally. The plurality of poles P are disposed in a space surrounded by the FOUP body 101. Each of the plurality of poles P extends, for example, along the front-rear direction. Each of the plurality of poles P is fixed, for example, to the rear surface 113B. A portion of the substrate S is placed on any of the poles P. As shown in FIG. 2, the plurality of poles P are arranged in the up-down direction correspondingly to the plurality of substrates S. Further, as shown in FIG. 3, the plurality of poles P are arranged side by side in the left-right direction. The plurality of poles P include a plurality of first poles P1, a plurality of second poles P2, and a plurality of third poles P3. The plurality of first poles P1 are disposed, for example, on an immediately the left side of the right side surface 113R, and arranged in the up-down direction. The plurality of second poles P2 are disposed, for example, at a substantially central position in the left-right direction of the FOUP body 101, and arranged in the up-down direction. The plurality of third poles P3 are disposed, for example, near the left side surface 113L, and arranged in the up-down direction. The first poles P1, the second poles P2, and the third poles P3 are provided in one-to-one correspondence to one substrate S. A space for supporting one substrate S is called a slot or a pocket (hereinafter called a slot for convenience of explanation). The slot corresponds to an accommodation region of the present disclosure. The FOUP 100 has a plurality of slots arranged in the up-down direction. The number of poles P supporting each substrate S is not limited to three.

The lid 102 is configured to open and close the opening 114. The lid 102 is attached to and detached from the FOUP body 101 by the load port 4. The lid 102 has a locking mechanism (not shown) that can change a state of the lid 102 between a state in which the lid 102 is fixed to the FOUP body 101 and a state in which the lid 102 is released from the FOUP body 101. The locking mechanism is locked and unlocked by a latch key (not shown).

### Overview of Camera Arrangement

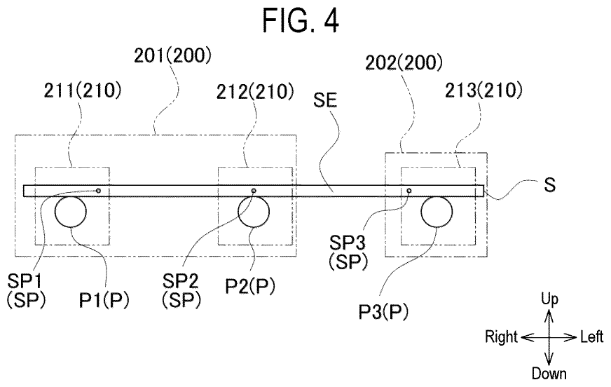

An overview of arrangement of the cameras 61 will be described with reference to FIGS. 3 and 4. FIG. 3 shows a positional relationship between the plurality of cameras 61 and the FOUP 100 when the plurality of cameras 61 are imaging the substrate S. FIG. 4 is a diagram showing a plurality of imaging regions 200 (first imaging region 201 and second imaging region 202).

As shown in FIG. 3, the first camera 63 is disposed between the first pole P1 and the second pole P2 in the left-right direction, for example. The first camera 63 is disposed at an appropriate position so that reflection light specularly reflected by the end surface SE in a vicinity of the first pole P1 and reflection light specularly reflected by the end surface SE in a vicinity of the second pole P2 travel toward the first camera 63. The first camera 63 is configured and disposed to image the first imaging region 201 (see FIG. 4), which is one of the imaging regions 200. As shown in FIG. 4, the first imaging region 201 is longer in the up-down direction than, for example, a length obtained by adding up a diameter of the pole P and the thickness of the substrate S. The first imaging region 201 extends in the left-right direction, for example, from a position on a right side of the first pole P1 to a position on a left side of the second pole P2.

Data relating to determination regions 210 (first determination region 211 and second determination region 212), which are portions of the first imaging region 201, is used as determination data to determine the accommodation state of the substrate S. The first determination region 211 is a region in a vicinity of the first pole P1. The second determination region 212 is a region in a vicinity of the second pole P2. For ease of explanation, the determination data relating to the first determination region 211 is referred to as first determination data. The determination data relating to the second determination region 212 is referred to as second determination data. The first determination data and the second determination data are also collectively referred to as low magnification data.

As shown in FIG. 3, the second camera 64 is disposed between the second pole P2 and the third pole P3 in the left-right direction, for example. The second camera 64 is disposed at an appropriate position so that reflection light specularly reflected by the end surface SE located near the third pole P3 travels toward the second camera 64. A distance between the second camera 64 and the third pole P3 in the left-right direction may be shorter than a distance between the second camera 64 and the second pole P2 in the left-right direction, for example. The second camera 64 is configured and disposed to image the second imaging region 202 (see FIG. 4), which is one of the imaging regions 200. As shown in FIG. 4, the second imaging region 202 is longer in the up-down direction than, for example, a length obtained by adding up the diameter of the pole P and the thickness of the substrate S. More specifically, the second imaging region 202 is longer in the up-down direction than, for example, a length obtained by adding up the diameter of the pole P and a thickness of two sheets of substrates S. The second imaging region 202 is set in advance by considering, for example, design tolerance of a size of the pole P. The second imaging region 202 extends in the left-right direction, for example, from a position on a right side of the third pole P3 to a position on a left side of the third pole P3. However, the present disclosure is not limited that described above. The third pole P3 is not necessarily included in the horizontal angle of view of the second camera 64.

Data relating to the determination region 210 (third determination region 213), which is a portion of the second imaging region 202, is used as determination data to determine the accommodation state of the substrate S. The third determination region 213 is a region in a vicinity of the third pole P3. Hereinafter, for convenience of explanation, the determination data relating to the third determination region 213 will be referred to as third determination data. In the present embodiment, the third determination data will also be referred to as high magnification data. The third determination data corresponds to image information in the present disclosure.

### Details of Arrangement of Cameras and Light Sources

A more detailed example of the arrangement of the cameras 61 and the light sources 62A to 62C will be described with reference to FIGS. 3 and 4. As shown in FIG. 3, when the camera 61 images the imaging region 200, the camera 61 focuses the reflection light by the light receiving lens 61a. In general, principal points (front principal point and rear principal point), focal points (front focal point and rear focal point), and nodal points (front nodal point and rear nodal point) of a lens are determined in advance according to specifications of the lens. Although not shown in the drawings, in the present embodiment, for example, a front nodal point of the light receiving lens 61a (a center point of a surface of the light receiving lens 61a on a side of the substrate S) is defined as a light receiving point RP for convenience of explanation. The light receiving point RP relating to the first camera 63 is called a first light receiving point RP1. The light receiving point RP relating to the second camera 64 is called a second light receiving point RP2.

Further, as shown in FIG. 4, a predetermined point included in each determination region 210 and included in the end surface SE is called a detection target point SP (see FIGS. 3 and 4) for convenience of explanation. Positions of the detection target point SP in the left-right direction and the front-rear direction are set in advance according to, for example, specifications of the FOUP 100, specifications of the substrate S, an arrangement of the light emitter 62, and the configuration and arrangement of the cameras 61. The detection target point SP included in the first determination region 211 is called a first detection target point SP1. As shown in FIG. 3, the first detection target point SP1 may be located, for example, on the left side of the first pole P1 (i.e., inner side than the first pole P1 in the left-right direction). The detection target point SP included in the second determination region 212 is called a second detection target point SP2. As shown in FIG. 3, the second detection target point SP2 may be located, for example, at substantially the same position as a center position of the second pole P2 in the left-right direction. The detection target point SP included in the third determination region 213 is called a third detection target point SP3. As shown in FIG. 3, the third detection target point SP3 may be located, for example, on the right side of the third pole P3 (i.e., inner side than the third pole P3 in the left-right direction). The position of each detection target point SP is not limited to that described above. For example, one or more detection target points SP may be set directly above a corresponding pole P. The first camera 63 images the imaging region 200 (first imaging region 201, see FIG. 4) including the first detection target point SP1 and the second detection target point SP2. The second camera 64 images the imaging region 200 (second imaging region 202, see FIG. 4) including the third detection target point SP3.

As shown in FIG. 3, for convenience of explanation, a virtual straight line passing through a predetermined light receiving point RP and a predetermined detection target point SP is called a virtual straight line VL. More specifically, the virtual straight line VL passing through the first light receiving point RP1 and the first detection target point SP1 is called a first virtual straight line VL1. The virtual straight line VL passing through the first light receiving point RP1 and the second detection target point SP2 is called a second virtual straight line VL2. The virtual straight line VL passing through the second light receiving point RP2 and the third detection target point SP3 is called a third virtual straight line VL3. The first virtual straight line VL1 intersects with, for example, the right side surface 113R of the FOUP 100. The second virtual straight line VL2 and the third virtual straight line VL3 intersect with, for example, the left side surface 113L of the FOUP 100.

### Basic Operation of Load Port

A basic operation of the load port 4 will be described with reference to FIGS. 5A to 6B. FIGS. 5A to 6B are right side views of the load port 4 in operation.

First, the FOUP 100 is placed on the stage 44 (see FIG. 5A). The LP control device 46 moves the stage 44 from the delivery position (see FIG. 5A) to the lid opening/closing position (see FIG. 5B). Subsequently, the LP control device 46 attracts and holds the lid 102 on the attracting holder of the door body 50, and unlocks the locking mechanism of the lid 102 by the latch key. Further, the LP control device 46 controls the motor 57 to move the door support 53 rearward (see the rightward arrow in FIG. 6A). Thus, the door body 50 moves from the predetermined closed position (see FIG. 5B) to the open position (see FIG. 6A). As a result, the lid 102 is removed from the FOUP body 101.

Subsequently, the LP control device 46 controls the motor 58 to move the door body 50 from the open position (see FIG. 6A) to the retracted position (see FIG. 6B). Accordingly, the plurality of cameras 61 and the like of the scanner 45 move downward together with the door body 50. In response to a command from the controller 66, the plurality of cameras 61 image a predetermined imaging region 200 (see FIG. 4) at a predetermined position in the up-down direction to obtain imaging data. The imaging region 200 includes a plurality of determination regions 210 (see FIG. 4; details will be described later) for determining the accommodation state of the substrate S. The controller 66 performs a mapping process based on the imaging data obtained by the plurality of cameras 61 (details will be described later).

After the mapping process is completed, the transfer robot 3 starts transferring the substrates S between the FOUP 100 and the processing apparatus 6. The processing apparatus 6 sequentially performs a predetermined process on some or all of the substrates S. Processed substrates S are returned to the FOUP 100 by the transfer robot 3. After all of the substrates S have been returned to the FOUP 100, the LP control device 46 causes the door mechanism 42 and the like to perform a reverse operation to the operation of opening the lid 102, and attaches the lid 102 to the FOUP body 101. As described above, a series of processes from when the FOUP 100 is transferred to the load port 4 to when the FOUP 100 becomes unloadable from the load port 4 is performed.

### Mapping Process

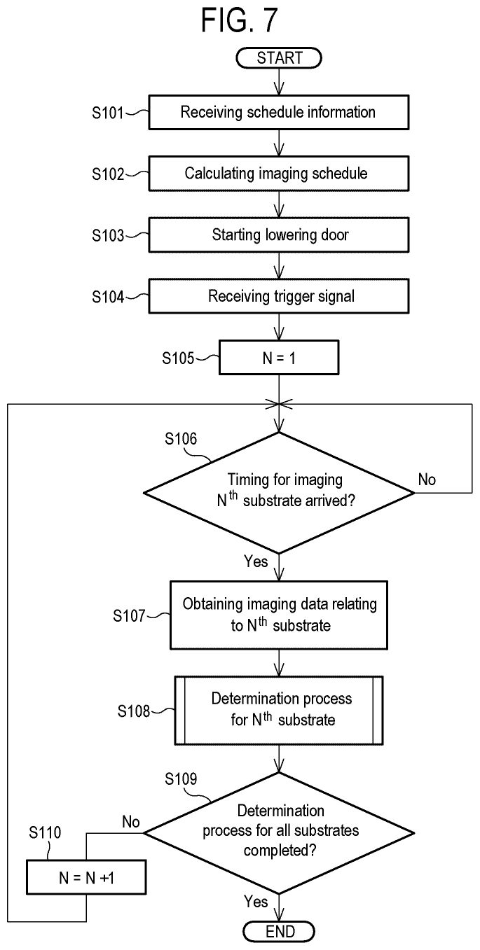

Next, an example of a mapping process (mapping method) executed by the load port 4 will be described with reference mainly to FIG. 7. FIG. 7 is a flowchart showing an entire mapping process.

An initial state is as follows. The FOUP 100 containing a plurality of substrates S is placed on the stage 44. The stage 44 is located at the lid opening/closing position. The lid 102 of the FOUP 100 is opened by the door mechanism 42. The door body 50 is located at the open position (see FIG. 6A).

First, the LP control device 46 transmits information (schedule information) relating to a schedule of imaging performed by the camera 61 to the controller 66. The schedule information is, for example, the specifications of the FOUP 100, the number of substrates S that can be stored in the FOUP 100, a position of an uppermost slot among the plurality of slots of the FOUP 100, a set value of a descending speed of the door body 50, or the like. The schedule information is, for example, sent in advance to the LP control device 46 from the controller (not shown) of the processing apparatus 6. The controller 66 receives the schedule information from the LP control device 46 (step S101 shown in FIG. 7). The controller 66 calculates an imaging schedule based on the schedule information (step S102). The imaging schedule is a schedule of a timing at which the cameras 61 are caused to perform imaging when a certain amount of time has elapsed after the controller 66 receives a predetermined trigger signal.

Subsequently, the LP control device 46 controls the motor 58 of the door mechanism 42 to start lowering the scanner 45 together with the door body 50 (and the door support 53) (step S103). At this time, the trigger sensor 65 detects a start of movement of the door support 53 and sends a detection signal to the controller 66. The controller 66 receives the detection signal as the trigger signal (step S104). Thereafter, the controller 66 causes each camera 61 to perform imaging based on the imaging schedule, for example, in the following procedure. The controller 66 causes the light sources 62A to 62C to emit light at least when each camera 61 is performing imaging (light emitting step).

The controller 66 sets, to an initial value, a counter for counting (determining) the substrates S accommodated in the FOUP 100 one by one sequentially from a top. More specifically, the controller 66 inputs, for example, “1” to a predetermined variable N (step S105).

Subsequently, the controller 66 determines whether or not a timing for imaging an N^{th} substrate S has arrived based on the imaging schedule (step S106). When the timing for imaging the N^{th} substrate S has not arrived (step S106: “No”), the scanner 45 continues to be lowered by the LP control device 46. When the timing for imaging the N^{th} substrate S has arrived (step S106: “Yes”), the controller 66 controls the plurality of cameras 61 to image the imaging region 200 relating to the N^{th} substrate S and obtains imaging data relating to the substrate S (imaging step, step S107). More specifically, the controller 66 causes the first camera 63 to image the first imaging region 201 and the second camera 64 to image the second imaging region 202. The controller 66 temporarily stores the imaging data obtained by these cameras 61 in, for example, a memory. Further, the controller 66 may store the imaging data in, for example, the above-mentioned internal storage not shown.

Subsequently, the controller 66 determines an accommodation state of the N^{th} substrate S based on determination data included in the imaging data (determination process, step S108).

Details of the determination process (determination step of the present disclosure) will be described later.

Subsequently, the controller 66 determines whether the determination process for all the substrates S has been completed (step S109). When the controller 66 determines that there is a substrate S that has not yet been subjected to the determination process (step S109: “No”), the controller 66 adds “1” to the variable N (step S110), for example, and returns to step S106.

When the determination process for all the substrates S has been completed (step S109: “Yes”), the controller 66 ends the mapping process.

### Determination Process

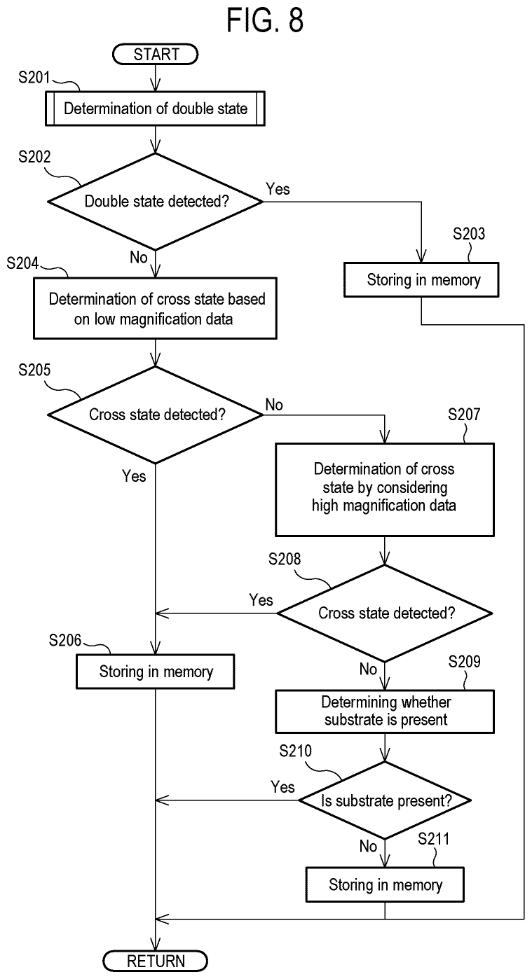

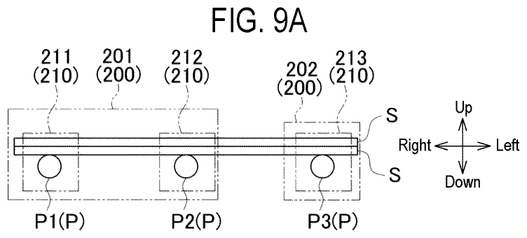

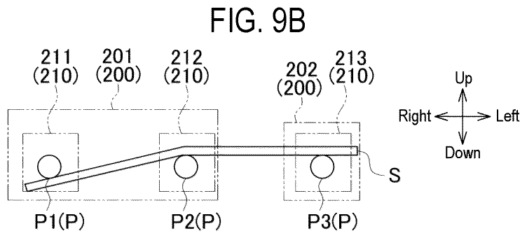

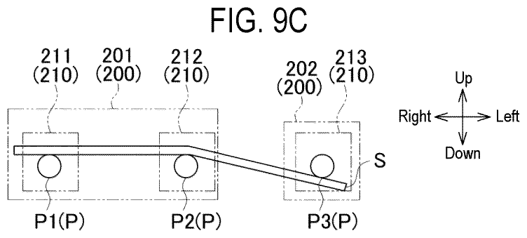

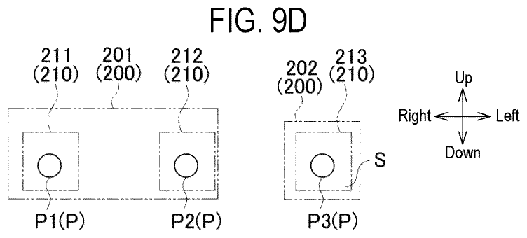

An example of the determination process for an accommodation state of each substrate S will be described with reference to FIGS. 8 to 9D. FIG. 8 is a flowchart showing a determination process for each substrate S. FIGS. 9A to 9D are diagrams for explaining determination of an accommodation state of the substrate S. In summary, the controller 66 determines whether the accommodation state of the N^{th} substrate S is a double state or a cross state, whether the N^{th} substrate S is not present, or whether the N^{th} substrate S is accommodated normally. In the following determination process, the controller 66 uses data relating to the determination region 210 of the imaging region 200 as determination data.

First, the controller 66 determines whether the accommodation state of the N^{th} substrate S is a double state or not (double determination; step S201 shown in FIG. 8). The double state is a state in which two (or more) substrates S overlapping with each other vertically are accommodated in one slot as shown in FIG. 9A. The double determination will be described in more detail later. When the double state is detected (step S202: “Yes”), the controller 66 stores information indicating that the accommodation state of the N^{th} substrate S is the double state in the memory (step S203). Thereafter, the controller 66 ends the determination for the N^{th} substrate S.

When the double state is not detected (step S202: “No”), the controller 66 determines whether or not the accommodation state of the N^{th} substrate S is a cross state (cross determination). The cross state is a state in which a portion of the substrate S is placed on one of a pair of poles P arranged in the left-right direction, and another portion of the substrate S is located below the pair of poles P as shown in FIG. 9B or 9C, for example.

As a procedure for the cross determination, first, the controller 66 determines whether the accommodation state of the N^{th} substrate S is a cross state based on, for example, low magnification data (step S204). More specifically, the controller 66 compares a position (hereinafter referred to as first substrate position) of the substrate S in the up-down direction, which is detected based on the first determination data, with a set position (hereinafter referred to as first set position) of the first pole P1, which corresponds to the substrate S, in the up-down direction. For example, when the first substrate position is lower than the first set position, the controller 66 determines that the accommodation state of the N^{th} substrate S is the cross state (i.e., the cross state is detected).

Further, the controller 66 compares a position (hereinafter referred to as second substrate position) of the substrate S in the up-down direction, which is detected based on the second determination data, with a set position (hereinafter referred to as second set position) of the second pole P2, which corresponds to the substrate S, in the up-down direction. The second set position may be set as a common position with the first set position in the up-down direction, or may be set independently from the first set position. For example, when the second substrate position is lower than the second set position, the controller 66 determines that the accommodation state of the N^{th} substrate S is the cross state (i.e., the cross state is detected).

When the cross state is detected (step S205: “Yes”), the controller 66 stores information indicating that the accommodation state of the N^{th} substrate S is the cross state in the memory (step S206). Thereafter, the controller 66 ends the determination for the N^{th} substrate S.

When the cross state is not detected based on the low magnification data (step S205: “No”), the controller 66 performs a cross determination by considering the high magnification data (step S207). The controller 66 compares a position (hereinafter referred to as third substrate position) of the substrate S in the up-down direction, which is detected based on the third determination data, with a set position (hereinafter referred to as third set position) of the third pole P3, which corresponds to the substrate S, in the up-down direction. The third set position may be a common position with the first set position and/or the second set position in the up-down direction, or may be set independently from the first set position and the second set position. For example, when the third substrate position is lower than the third set position, the controller 66 determines that the accommodation state of the N^{th} substrate S is the cross state (i.e., the cross state is detected). When the cross state is detected (step S208: “Yes”), the controller 66 executes aforementioned step S206 and ends the determination for the N^{th} substrate S.

When the cross state is not detected even when the high magnification data is considered (step S208: “No”), the controller 66 determines whether or not the substrate S is present (step S209). More specifically, the controller 66 determines whether or not the substrate S is detected in any of the first determination region 211, the second determination region 212, and the third determination region 213 based on the determination data. When the substrate S is not detected in any of the determination regions 210 (see FIG. 9D), the controller 66 determines that the N^{th} substrate S is not preset (step S210: “No”). In this case, the controller 66 stores information indicating that the N^{th} substrate S is not preset in the memory (step S211). Thereafter, the controller 66 ends the determination for the N^{th} substrate S. When the substrate S is detected in any of the determination regions 210, the controller 66 determines that the N^{th} substrate S is preset (i.e., is correctly stored) (step S211: “No”). In this case, the controller 66 ends the determination regarding for N^{th} substrate S as it is. As described above, the determination process for the N^{th} substrate S is completed.

Here, the inventors of the present disclosure have been studying ways to further improve detection accuracy of the above-mentioned double state. As an example of a conventional specific method of double determination, a method of comparing a pixel value, which indicates brightness (called luminance) of a pixel at each coordinate in the thickness direction (up-down direction) of the substrate S, in the third determination data with a predetermined threshold value may be considered. In this method, it is determined that the substrate S is present at coordinates relating to a pixel having a pixel value equal to or greater than the threshold value. Further, by comparing a length in the thickness direction (i.e., thickness) of a portion having a pixel value equal to or greater than the threshold value with a reference value of thickness, it is determined whether or not two or more substrates S are present. However, in the method of comparing the pixel value itself with the threshold value, influence of light reflected from the inner wall surface 113 of the FOUP 100 is significant according to a type of FOUP 100. Therefore, further improvement of the detection accuracy may be required.

In addition, in the method of comparing the detected value of the thickness of the substrate S with the reference value, the following problem may occur. According to a processing state of the end surface SE of the substrate S, a portion of the end surface SE, which specularly reflects light toward the second camera 64, may have a length in the thickness direction significantly shorter than an actual length in the thickness direction (i.e., thickness) of the substrate S. In this case, even when two or more substrates S are overlapped with each other, a detected value of the thickness of the substrate S may not exceed the reference value, resulting in an erroneous determination.

Therefore, in order to more reliably detect the double state, the controller 66 of the present embodiment performs the following double determination (determination of the present disclosure).

### Details of Double Determination

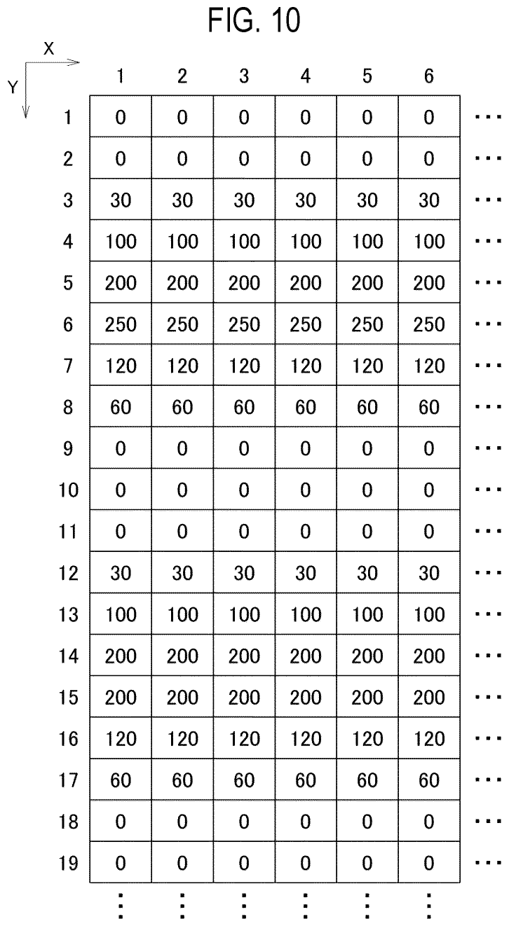

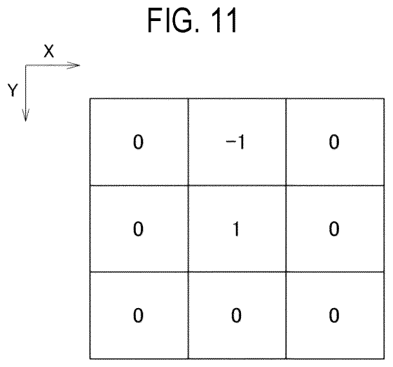

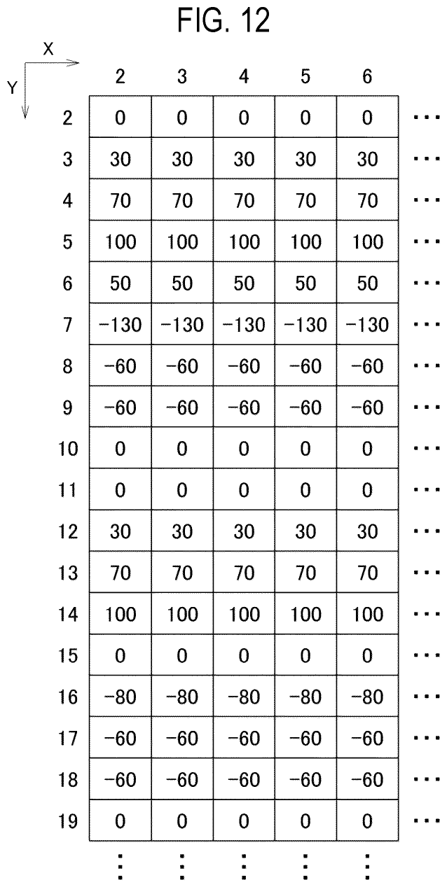

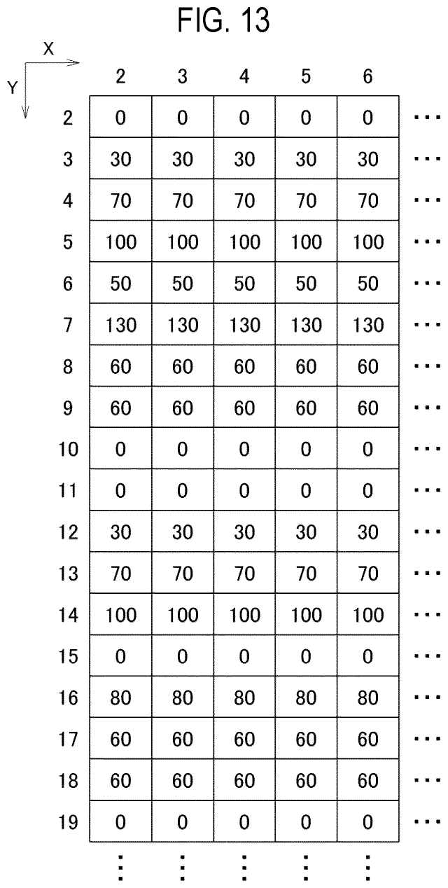

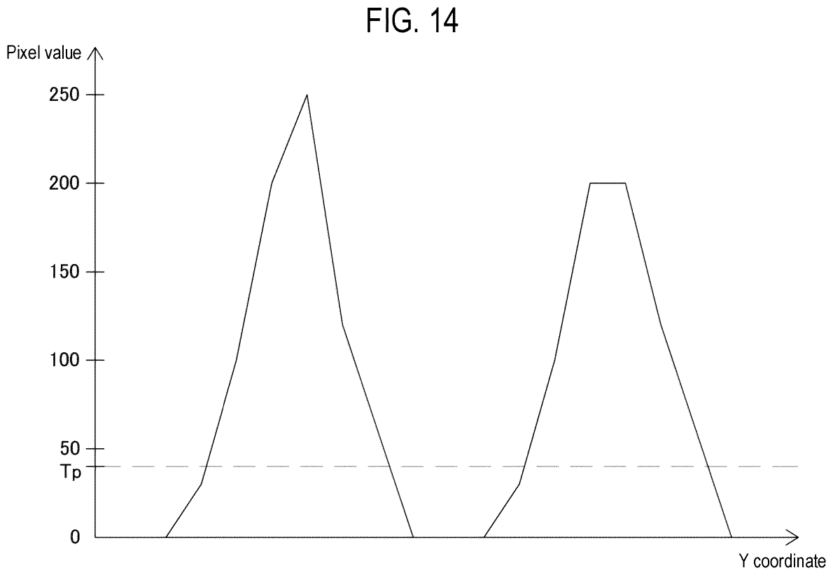

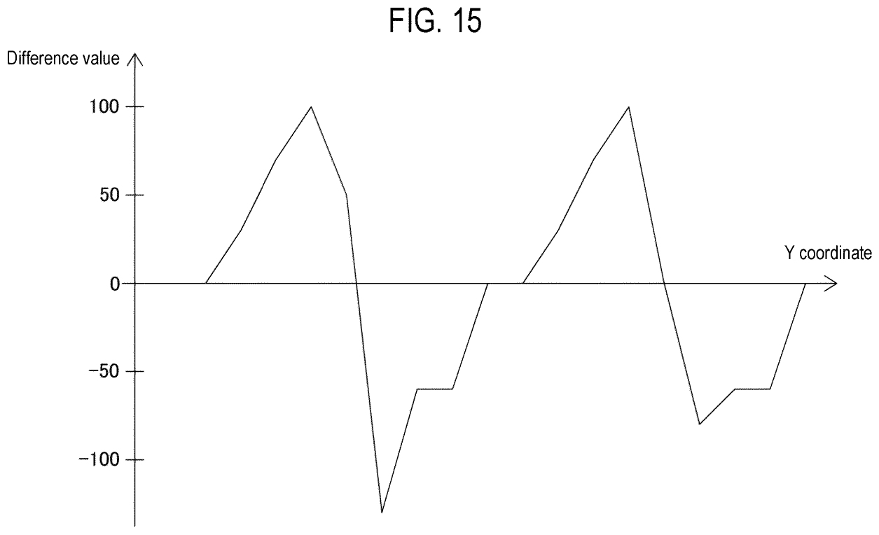

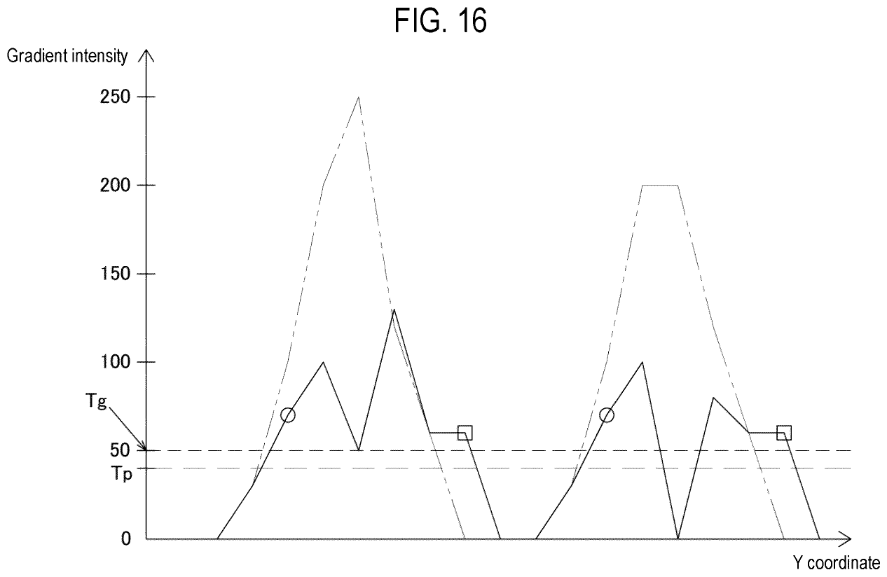

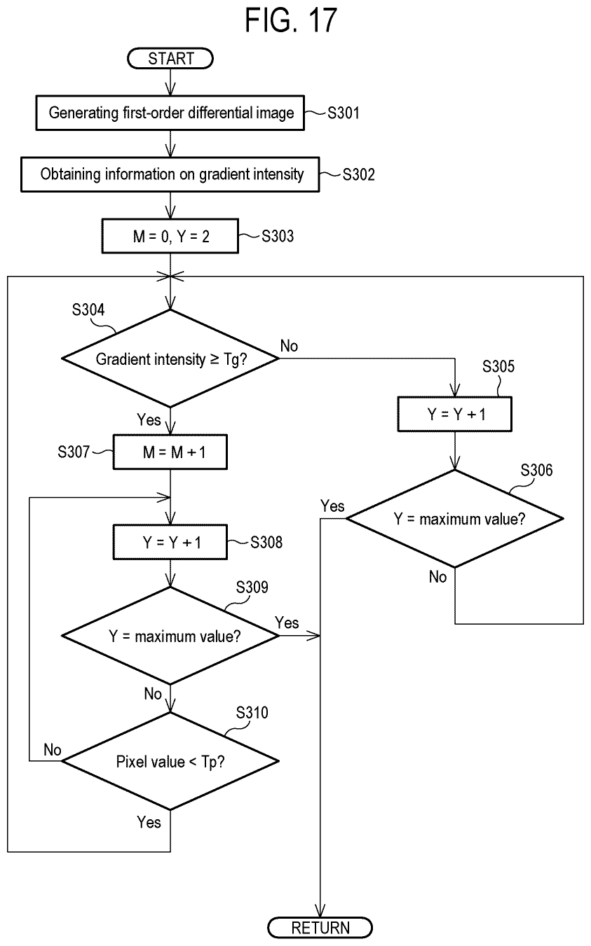

Details of the double determination will be described with reference to FIGS. 10 to 17. FIG. 10 is a diagram showing an example of a set of pixel values, i.e., an example of pixel values at respective coordinates of the third determination data. FIG. 11 is a diagram showing a first-order differential filter. FIG. 12 is a diagram showing a set of difference values obtained by applying the first-order differential filter to the pixel values. FIG. 13 is a diagram showing a set of absolute values of the difference values (also called gradient intensities). In FIGS. 10 to 13, a left-right direction (direction of X coordinates) on the paper plane corresponds to the left-right direction in the present embodiment, and an up-down direction (direction of Y coordinates) on the paper plane corresponds to the up-down direction in the present embodiment. FIG. 14 is a graph showing a relationship between the pixel values and the Y coordinates (described later). FIG. 15 is a graph showing a relationship between the difference values and the Y coordinates. FIG. 16 is a graph showing a relationship between the gradient intensities (absolute values of difference values) and the Y coordinates. FIG. 17 is a flowchart showing a procedure of double determination.

The controller 66 performs the double determination by using, for example, the third determination data. The third determination data is a set of multiple pixel values associated with two-dimensional coordinates consisting of X coordinates corresponding to the left-right direction and Y coordinates corresponding to the up-down direction. FIG. 10 shows multiple frames in a matrix form. The numbers (“1” to “6”) arranged in the left-right direction on an upper side of the multiple frames indicate the X coordinates. The numbers (“1” to “19”) arranged in the up-down direction on a left side of the multiple frames shown in FIG. 10 indicate the Y coordinates. The numbers written in the respective multiple frames indicate the pixel values associated with the respective coordinates. Each pixel value is an integer within a range of 0 to 255. A larger pixel value means that a location corresponding to that pixel is brighter. The multiple numbers written outside the multiple frames indicate coordinates added for convenience of explanation. It should be noted that the multiple pixel values shown in FIG. 10 are convenient values for easily explaining the present embodiment and do not necessarily match pixel values actually obtained by the second camera 64. For ease of explanation, the pixel values shown in FIG. 10 are constant and do not depend on the X coordinates. The pixel values change depending only on the Y coordinates. Hereinafter, a direction along the X coordinates (left-right direction) is also referred to as an X direction, and a direction along the Y coordinates (up-down direction) is also referred to as a Y direction.

First, the controller 66 performs, for example, a first-order differential process on the third determination data in the Y direction to generate a first-order differential image (step S301 shown in FIG. 17). More specifically, the controller 66 applies, for example, a well-known first-order differential filter (see FIG. 11) to the third determination data. The first-order differential filter is a first-order differential filter relating to the Y coordinate. Thus, a set of multiple difference values associated with multiple coordinates (see FIG. 12) is obtained. A difference value in the present embodiment is a difference between a pixel value relating to one coordinate of the third determination data and a pixel value relating to a coordinate immediately before the one coordinate in the Y direction. Information on the difference value corresponds to information on an amount of change according to a coordinate in the thickness direction in the present disclosure. In addition, the difference values are not obtained at coordinates corresponding to either X=1 or Y=1 (see FIG. 12). Hereinafter, for convenience of explanation, the set of difference values is also referred to as first-order differential image.

Subsequently, the controller 66 obtains data of a set of absolute values of the difference values corresponding to the respective coordinates (see FIG. 13). Hereinafter, for convenience of explanation, an absolute value of a difference value is also referred to as a gradient intensity. That is, the controller 66 obtains information on the gradient intensity (step S302). The gradient intensity also corresponds to information on the amount of change according to the coordinate in the thickness direction in the present disclosure.

A graph showing a relationship between the pixel values and the Y coordinates is shown in FIG. 14. The pixel value at each Y coordinate may be, for example, an average value of multiple pixel values arranged in the X direction in FIG. 10. Alternatively, the pixel values may be, for example, values obtained by extracting only pixel values associated with a specific X coordinate along the Y direction. Further, for reference, a graph showing a relationship between the difference values and the Y coordinates is shown in FIG. 15. Furthermore, a graph showing a relationship between the gradient intensities and the Y coordinates is shown in FIG. 16. FIG. 16 also includes a graph showing the relationship between the pixel values and the Y coordinates (see the two-dot chain line).

For example, the controller 66 stores in advance information on a threshold value (see Tp shown in FIG. 14) of the pixel values. The value of Tp is, for example, 40. The controller 66 also stores in advance information on a threshold value (see Tg shown in FIG. 16) of the gradient intensities. The value of Tg is, for example, 50.

The controller 66 counts the number of substrates S in the third determination region 213 (see FIGS. 9A to 9D) by using, for example, data on the gradient intensity and the third determination data. More specifically, the controller 66 determines, for example, whether the gradient intensity is equal to or greater than Tg in ascending order of Y coordinates (such determination processing is generally called scan line processing along the Y direction). In other words, in the present embodiment, the controller 66 detects a start of rising in the pixel values.

This will be described in more detail later.

The controller 66 sets the number of detections of the substrates S to zero (M=0; see step S303). The controller 66 also sets the Y coordinate to “2” (Y=2; see step S303). These processes are initial setting processes for counting the number of substrates S accommodated in the N^{th} slot.

The controller 66 determines whether the gradient intensity at the Y coordinate to be determined is equal to or greater than Tg (step S304). When the gradient intensity is less than Tg (step S304: “No”), the controller 66 updates the Y coordinate (Y=Y+1; step S305), and determines whether Y is a predetermined maximum value (step S306). The maximum value refers to a maximum Y coordinate associated with the pixel values in the determination region relating to the third determination data (hereinafter, the same applies). In addition, a value obtained by subtracting one from the maximum value (hereinafter, simply expressed as “maximum value−1”) is a maximum Y coordinate associated with the gradient intensities (and the difference values). When Y is not the maximum value (step S306: “No”), the controller 66 returns to step S304. When Y is the maximum value (step S306: “Yes”), the double determination (counting the number of substrates S) in the N^{th} slot ends.

Returning to the explanation of step S304, when the gradient intensity is equal to or greater than Tg (step S304: “Yes”), the controller 66 adds “1” to the number of detections of the substrates S (M=M+1; step S307). Subsequently, the controller 66 updates the Y coordinate in the same manner as in step S305 (step S308). Thereafter, the controller 66 determines whether Y is the maximum value or not (step S309) in the same manner as in step S306. When Y is the maximum value (step S309: “Yes”), the counting the number of substrates S ends. When Y is not the maximum value (step S309: “No”), the controller 66 determines whether the pixel value is less than Tp (step S310). While the pixel value is equal to or greater than Tp (step S310: “No”), the controller 66 returns to step S308 and repeats updating the Y coordinate. This is to prevent the already detected substrates S from being counted redundantly. When the pixel value is less than Tp (step S310: “Yes”), the controller 66 returns to step S304. The pixel value being less than Tp means that the detection of the substrate S has been interrupted. Returning to step S304 means performing preparation for counting the next substrate S. Through the above-described procedure, the double determination of the present embodiment is performed.

By performing the above-described determination, the number of substrates S is detected according to the number of times the start of rising in pixel values is detected (see the circular marks on the solid line graph in FIG. 16). Information on the number of times the start of rising in pixel values is detected corresponds to numerical information of the present disclosure.

As described above, the determination is made by using information on the amount of change in pixel value along the thickness direction. Since the substrate S is generally very thin compared to the inner wall surface 113 of the FOUP 100, the pixel value corresponding to the light reflected from the end surface SE of the substrate S changes rapidly according to the coordinate in the thickness direction. Conversely, since the inner wall surface 113 of the FOUP 100 has a certain length in the thickness direction, the light reflected from the inner wall surface 113 of the FOUP 100 can be detected over a wide region in the thickness direction. For this reason, it is presumed that the amount of change in pixel value corresponding to the light reflected from the inner wall surface 113 in the thickness direction is gentler than the amount of change in pixel value relating to the end surface SE of the substrate S. Therefore, by using information on the change in pixel value in the thickness direction, the influence of the light reflected from the inner wall surface 113 of the FOUP 100 can be suppressed during the double determination. Accordingly, the double state (the accommodation state of the substrates) can be detected more reliably.

Further, the double determination can be performed by counting the number of substrates S in each slot. Accordingly, the double state can be detected more reliably.

Furthermore, the information on the pixel values can be used as an auxiliary in the double determination. Accordingly, compared to a case where only the information on the amount of change in pixel value is used, it is possible to further improve accuracy of the double state detection.

Next, modifications of the above-described embodiment will be described. The same components as those in the embodiment will be designated by like reference numerals, and the description thereof will be omitted as appropriate.

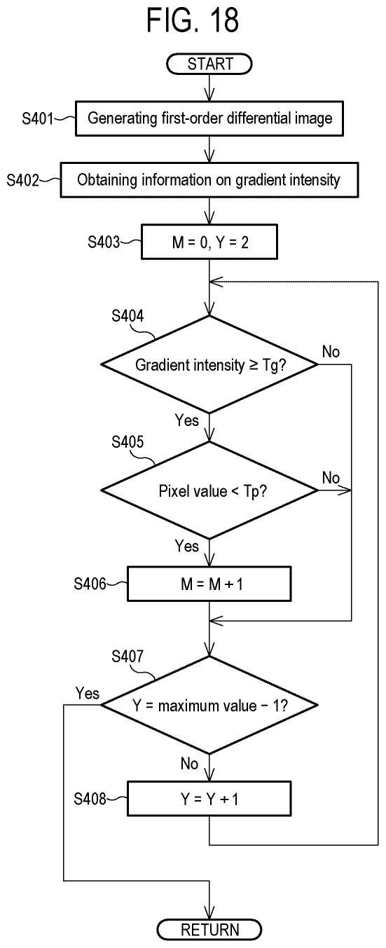

(1) In the above-described embodiment, the controller 66 counts the number of times the pixel value starts rising. However, the present disclosure is not limited thereto. Instead of performing the process described in the above embodiment, the controller 66 may count the number of times the pixel value stops decreasing. Hereinafter, a specific description will be given with reference to the flowchart shown in FIG. 18. First, the controller 66 generates a first-order differential image (step S401) and obtains information on gradient intensity (step S402) in the same manner as in the above embodiment. The controller 66 also sets the number of detections of the substrates S to zero and sets the Y coordinate to “2” (step S403). Subsequently, the controller 66 determines whether the gradient intensity is equal to or greater than Tg (step S404). When the gradient intensity is equal to or greater than Tg (step S405: “Yes”), the controller 66 further determines whether the pixel value is less than Tp (step S405). When the pixel value is less than Tp (step S405: “Yes”), the controller 66 adds “1” to the number of detections of the substrates S (step S406). That is, an end of decreasing in the pixel values is counted only when the gradient intensity is equal to or greater than Tg and the pixel value is less than Tp. Subsequently, the controller 66 determines whether Y is “maximum value−1” described above (step S407). When Y is not “maximum value−1” (step S407: “No”), the controller 66 updates the Y coordinate (step S408) and returns to step S404. When Y is “maximum value−1” (step S408: Yes), the double determination ends.

By performing the above-described determination, the number of substrates S is detected according to the number of times the end of decreasing in the pixel values is detected (see the square marks on the solid line graph in FIG. 16). In this modification, information on the number of times the end of decreasing in the pixel values is detected corresponds to the numerical information of the present disclosure.

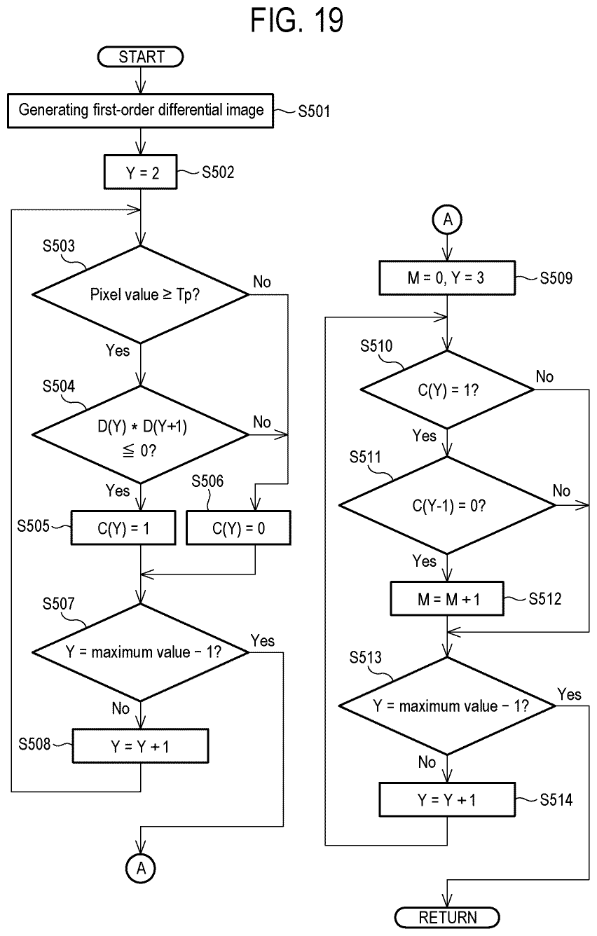

(2) In the above-described embodiment and modification, the controller 66 counts the number of times the pixel value starts rising or the number of times the pixel value stops decreasing. However, the present disclosure is not limited thereto. The controller 66 may count the number of peaks of the pixel values in the following manner. Hereinafter, a specific description will be given with reference to the flowchart shown in FIG. 19. First, the controller 66 generates a first-order differential image (step S501) in the same manner as in the above embodiment. However, the controller 66 may not obtain information on the gradient intensity. In addition, the controller 66 sets the Y coordinate to “2” (step S502). However, the controller 66 may not set the number of detections of the substrates S to zero at this stage. The controller 66 picks up a candidate for a peak of the pixel values in the following steps S503 to S506. For convenience of explanation, the difference value at each Y coordinate is defined as D(Y). In addition, for convenience of explanation, a function indicating whether a candidate for the peak of the pixel value has been found at each Y coordinate is defined as C(Y). The controller 66 determines whether the pixel value is equal to or greater than Tp (step S503). When the pixel value is equal to or greater than Tp (step S503: “Yes”), the controller 66 further determines whether a product of D(Y) and D(Y+1) is equal to or less than zero (step S504). The product of D(Y) and D(Y+1) being equal to or less than zero means that the pixel value has changed from increasing to decreasing according to a change in the Y coordinate (see FIGS. 14 and 15). That is, it can be estimated that the peak of the pixel value has been found. When the product of D(Y) and D(Y+1) is equal to or less than zero (step S504: “Yes”), the controller 66 sets the value of C(Y) to “1” (step S505). When the determination result in either step S503 or step S504 is “No,” the controller 66 sets the value of C(Y) to “0” (step S506). C(Y) being “1” means that a candidate for the peak of the pixel value has been found at this Y coordinate. C(Y) being “0” means that the peak of the pixel value was not found at this Y coordinate. Subsequently, the controller 66 determines whether Y is “maximum value−1” (step S507). When Y is not “maximum value−1” (step S507: “No”), the controller 66 updates the Y coordinate (step S508) and returns to step S503. When Y is “maximum value−1” (step S507: “Yes”), the controller 66 proceeds to a next step (see the circled “A”in FIG. 19).

In the next step and thereafter, the controller 66 verifies whether the candidate for the peak of the pixel value is a true peak, and counts the number of true peaks. In this modification, information on the number of true peaks corresponds to the numerical information of the present disclosure. First, the controller 66 sets the number of detections of the substrate S to zero, and sets the Y coordinate to, for example, “3” (step S509). The reason for setting an initial value of the Y coordinate to “3” during the verification will be described later. Subsequently, the controller 66 determines whether C(Y) is “1” or not (step S510). When C(Y) is “1,” the controller 66 further determines whether C(Y−1) is “0” or not (step S511). Only when the determination result of step S511 is “Yes,” the controller 66 adds “1” to the number of detections of the substrates S (step S512). The reason is as follows. That is, when the above-mentioned product of D(Y) and D(Y+1) is zero, D(Y) or D(Y+1) is zero. Therefore, the product of D(Y−1) and D(Y) or the product of D(Y+1) and D(Y+2) is also zero. In such a case, multiple peak candidates relating to the same substrate S are found. Thus, the processing described above is required to avoid duplication in count. The controller 66 may not only determine whether C(Y−1) is “0,” but also may perform a similar determination over a wider range in the Y coordinate to avoid duplication in count. Subsequently, the controller 66 determines whether Y is “maximum value−1” (step S513). When Y is not “maximum value−1” (step S513: “No”), the controller 66 updates the Y coordinate (step S514) and returns to step S510. When Y is “maximum value−1” (step S514: “Yes”), the double determination ends.

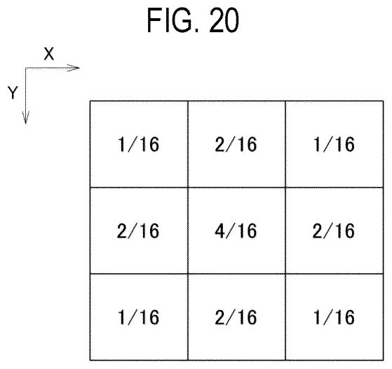

(3) The controller 66 may perform a noise removal process on the third determination data before applying the first-order differential filter to the third determination data. More specifically, the controller 66 may apply, for example, a well-known Gaussian filter (see FIG. 20) to the third determination data. This can further improve the accuracy of the above-mentioned determination.

(4) In the above-described embodiment, the controller 66 applies the first-order differential filter to the third determination data. However, the present disclosure is not limited thereto. The controller 66 may apply, for example, a well-known Sobel filter to the third determination data instead of the first-order differential filter.

(5) In the above-described embodiment, the controller 66 counts the number of substrates S in the third determination region 213. However, the present disclosure is not limited thereto.

The controller 66 may perform the double determination by detecting the thickness of the substrates S in the third determination region 213.

(6) In the above-described embodiment, the controller 66 performs the double determination by using data on the gradient intensity or the difference value and data on the pixel value. That is, the data on the pixel value is used auxiliary in the double determination.

However, the present disclosure is not limited thereto. The controller 66 may use only the data on the gradient intensity and/or the difference value in the double determination, for example, without directly using the data on the pixel value. For example, the controller 66 may determine that the substrate has started to be detected when the gradient intensity becomes equal to or greater than Tg, and then may determine that the peak of the pixel values has been found based on the product of D(Y) and D(Y+1). The controller 66 may count the number of detections of the substrate S by combining these determinations, for example.

Alternatively, a program, which performs the double determination by using only the data on the pixel value and without using the data on the gradient intensity or the difference value, may be stored in the controller 66. The controller 66 may be programmed to select one of the following three modes as a determination mode for the double determination. A first determination mode is a mode that uses the data on the gradient intensity or the difference value data and the data on the pixel value. A second determination mode is a mode that uses only the data on the gradient intensity and/or the difference value. A third determination mode is a mode that uses only the data on the pixel value.

(7) In the above-described embodiment, the controller 66 performs the double determination by using the third determination data. However, the present disclosure is not limited thereto. The controller 66 may perform the double determination by using the first determination data or the second determination data.

(8) In the above-described embodiment, the number of cameras 61 is two. However, the present disclosure is not limited thereto. The number of cameras 61 may be three or more. Alternatively, the number of cameras 61 may be one.

(9) A type of container is not limited to the FOUP 100. The present disclosure may also be applied to containers (not shown) other than the FOUP 100.

(10) A shape of the substrate S may be a shape other than a substantially rectangular shape when viewed from the up-down direction. The substrate S may have, for example, a substantially circular plate shape.

(11) In the above-described embodiment, the scanner 45 is fixed to the door body 50 (i.e., the scanner 45 is driven by the motor 58 to move in the up-down direction together with the door body 50). However, the present disclosure is not limited thereto. The scanner 45 may be fixed to another member.

(12) In the above-described embodiment, the controller 66 causes each camera 61 to perform imaging based on the imaging schedule. However, the present disclosure is not limited thereto. The controller 66 may cause each camera 61 to perform imaging while determining, for example, a position of the scanner 45 in the up-down direction.

(13) In the above-described embodiments, the LP control device 46 and the controller 66 are provided separately. However, the present disclosure is not limited thereto. For example, the LP control device 46 may be equipped with the controller 66. Alternatively, the LP control device 46 may have a function of controlling each camera 61 instead of the controller 66. When the LP control device 46 has the function described above, the LP control device 46 corresponds to the determiner of the present disclosure. Alternatively, for example, the control device 5 of the EFEM 1 may control the load port 4. In this case, the control device 5 corresponds to the determiner of the present disclosure.

(14) The load port 4 may be placed on equipment other than the EFEM 1.

(15) The present disclosure may be applied to mapping devices other than the load port 4.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A mapping device for detecting an accommodation state of a plurality of substrates, which are accommodated in a container while being arranged in a predetermined thickness direction, comprising:
a light emitter configured to emit light toward at least an interior of the container;
an imager configured to image a predetermined imaging region by sensing reflection light of the light emitted from the light emitter to obtain image information; and
a determiner configured to determine the accommodation state of the substrates by using the image information,
wherein the image information includes information on a plurality of pixel values that indicate intensities of the reflection light at corresponding coordinates in the thickness direction, and
wherein the determiner determines, by using information on an amount of change in the plurality of pixel values according to the coordinates in the thickness direction, whether two or more substrates are accommodated in an accommodation region in the imaging region, the accommodation region being a region for accommodating one of the plurality of substrates.

2. The mapping device of claim 1, wherein the determiner obtains numerical information indicating one of a number of peaks of the pixel values, a number of times the pixel values start increasing, and a number of times the pixel values stop decreasing, based on the information on the amount of change, and in the determination, counts a number of the substrates in the accommodation region based on the numerical information.

3. The mapping device of claim 2, wherein the determiner uses, in the determination, information on the pixel values in addition to the information on the amount of change.

4. The mapping device of claim 1, wherein the determiner uses, in the determination, information on the pixel values in addition to the information on the amount of change.

5. A mapping method performed in a mapping device for detecting an accommodation state of a plurality of substrates, which are accommodated in a container while being arranged in a predetermined thickness direction, comprising:
emitting light toward at least an interior of the container;
imaging a predetermined imaging region by sensing reflection light of the light to obtain image information; and
determining the accommodation state of the substrates by using the image information,
wherein the image information includes information on a plurality of pixel values that indicate intensities of the reflection light at corresponding coordinates in the thickness direction, and
wherein the determining includes determining, by using information on an amount of change in the plurality of pixel values according to the coordinates in the thickness direction, whether two or more substrates are accommodated in an accommodation region in the imaging region, the accommodation region being a region for accommodating one of the plurality of substrates.
